(19) United States
(12) Patent Application Publication
(10) Pub. No.: US 2014/0332952 A1
(43) Pub. Date: Nov. 13, 2014

(54) SEMICONDUCTOR STRUCTURE AND METHOD FOR TESTING THE SAME

(71) Applicant: UNITED MICROELECTRONICS CORP., Hsinchu (TW)

(72) Inventors: Chien-Li Kuo, Hsinchu City (TW); Yung-Chang Lin, Taichung City (TW); Chun-Ting Yeh, Taipei City (TW); Kuei-Sheng Wu, Miaoli County (TW)

(73) Assignee: UNITED MICROELECTRONICS CORP., Hsinchu (TW)

(21) Appl. No.: 13/890,397

(22) Filed: May 9, 2013

(51) Int. Cl. H01L 23/48; H01L 21/66

(52) U.S. Cl. CPC H01L 23/481; H01L 22/14
USPC 257/737; 438/18

(57) ABSTRACT

A semiconductor structure comprising a substrate, a dielectric layer, a conductor post, a first conductive layer structure and a second conductive layer structure is provided. The substrate comprises an opening structure. The dielectric layer is disposed on a sidewall of the opening structure. The conductor structure is disposed in the opening structure and covers the dielectric layer. The first and second conductive layer structures are electrically connected to the conductor post. A voltage difference is existed between the first and second conductive layer structures, such that a current is passing through the first conductive layer structure, the opening structure and second conductive layer structure. A resistance values is related to the voltage difference and the current. A dimension of the opening structure is 10 times greater than a dimension of the first and second conductive layer structures.

### BACKGROUND OF THE INVENTION

1. Field of the Invention

This invention is related to a semiconductor structure and a testing method for testing the same, and more particular to a semiconductor structure and a testing method for testing a quality of an opening structure in the semiconductor structure.

2. Description of the Related Art

Interconnection technology in a semiconductor structure is widely used in three dimension IC. For example, a via, such as a through silicon via (TSV), can be used to penetrate a silicon substrate and interconnect chips vertically. Three dimension IC package follows the Moore's Law and can improve the system integration and efficiency by a relatively low cost.

Not only a good via manufacturing technology, but also a fast and specific testing method for testing the quality of a via is important. A fast and specific testing method for testing the quality of a via can confirm the reliability and stability of the product. Therefore, how to test the quality of the via simply and in a fast speed is important and critical for avoiding a current leakage and open circuit in a semiconductor having the via.

### SUMMARY OF THE INVENTION

The invention is related to a semiconductor structure and a testing method for testing the same. The testing method can be applied to test the quality of a conductor post in a via or an electrical connection between the opening structure and the conductive bump in the semiconductor structure, after a first metal layer procedure. The testing method has a plurality of advantages, such as simple testing procedures, low complexity for result analysis, and fast testing time.

According to a first aspect of the present invention, a semiconductor structure comprising a substrate, a dielectric layer, a conductor post, a first conductive layer structure and a second conductive layer structure are provided. The substrate comprises an opening structure. The dielectric layer is disposed on a sidewall of the opening structure. The conductor post is disposed in the opening structure and covers the dielectric layer. The first and second conductive layer structures are electrically connected to the conductor post. A voltage difference is existed between the first and second conductive layer structures, such that a current is passing through the first conductive layer structure, the opening structure and second conductive layer structure. A resistance values is related to the voltage difference and the current. A dimension of the opening structure is 10 times greater than a dimension of the first and second conductive layer structures.

According to a second aspect of the present invention, a method for testing a semiconductor structure is provided. The method comprises following steps. A semiconductor structure is provided. The semiconductor structure comprises a substrate, a dielectric layer, a conductor post, a first conductive layer structure and a second conductive layer structure. The substrate has an opening structure. The dielectric layer is disposed on a side surface of the opening structure, the conductor post is disposed in the opening structure and covering the dielectric layer. The first conductive layer structure and the second conductive layer structure are electrically connected with the conductor post, and the first conductive layer structure and the second conductive layer structure are respectively disposed at opposite sides of a central axis of the opening structure. A dimension of the opening structure is at least 10 times greater than a dimension of the first conductive layer structure and a dimension of the second conductive layer structure. A voltage difference is applied between the first conductive layer structure and the second conductive layer structure. A current passing through the first conductive layer structure, the opening structure and the second conductive layer structure is measured. A resistance is obtained according to the voltage difference and the current. A testing result is determined according to the resistance.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a diagram showing a cross section view of a semiconductor structure according to one embodiment of the invention.

FIG. 2 illustrates a diagram showing a top view of a semiconductor structure in FIG. 1.

FIG. 3 illustrates a diagram showing a cross section view of semiconductor structure according to one embodiment of the invention.

FIG. 4 illustrates a diagram showing a substrate of the semiconductor structure in FIG. 1 after an unilateral thinning process.

FIG. 5 illustrates a diagram showing a part of a cross section view of a semiconductor structure according to one embodiment of the invention.

FIG. 6 illustrates a testing method with a diagram showing a top view of a semiconductor structure in FIG. 5 in one direction of x-y plane.

FIG. 7 illustrates a testing method with a diagram showing a top view of a semiconductor structure in FIG. 5 in another one direction of x-y plane.

### DETAILED DESCRIPTION OF THE INVENTION

### First Embodiment

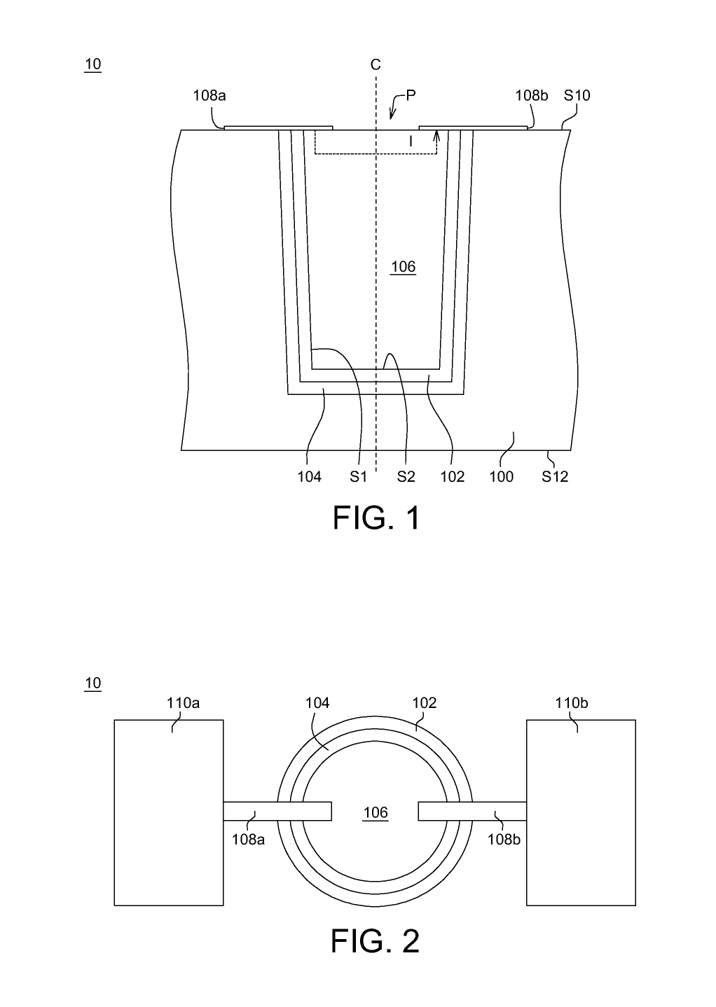

FIG. 1 illustrates a diagram showing a cross section view of a semiconductor structure 10 according to one embodiment of the invention. As shown in FIG. 1, a semiconductor structure 10 comprises a substrate 100, a barrier layer 102, an oxide layer 104 (dielectric layer), a conductor post 106, a first conductive layer structure 108a and a second conductive layer structure 108b. The substrate has an opening structure P. The oxide layer 104 is disposed on a side surface S1 and a bottom surface S2 of the opening structure P, the barrier layer 102 is disposed on the oxide layer 104. The conductor post 106 is disposed in the opening structure P, and covers the barrier layer 102. The first conductive layer structure 108a and the second conductive layer structure 108b are respectively disposed at two opposite sides of a central axis C of the opening structure P, and are electrically connected to the conductor post 106. In order to highlight the characteristics of the embodiments of the invention, parts of the elements are not illustrated according to and actual proportion.

In one embodiment, the substrate 100 has a first surface S10 and a second surface S12 opposite to the first surface S10. The opening structure P is passing through and exposed from the first surface S10. The first conductive layer structure 108a and second conductive layer structure 108b are disposed on the first surface S10 of the substrate 100. The conductor post 106 can be formed by a metal depositing process and is filled inside the opening structure P. The material of the conductor post 106 can be conductive material, such as copper (Cu), tungsten (W) and polysilicon, etc.

The first conductive layer structure 108a and the second conductive layer structure 108b are disposed on the first surface S10 (upper surface) of the substrate 100, and extends from the first surface S10 of the substrate 100 to the conductor post 106, exceeds the oxide layer 104 and barrier layer 102 and contact a surface of the conductor post.

A dimension of the opening structure P (such as a height) is at least ten times greater than a dimension (such as height) of the first conductive layer structure 108a and a dimension (such as height) of the second conductive layer structure 108b. In one embodiment, the dimension of the opening structure P is 100 times greater than that of the first conductive layer structure 108a and second conductive layer structure 108b. For example, the height of the opening structure P is 40 μm, and the height of the first conductive layer structure 108a and the height of the second conductive layer structure 108b are 200 nm. The height of the structure is merely one example embodiment, and the invention is not limited thereto.

A voltage difference (not illustrated) exist between the first conductive layer structure 108a and the second conductive layer structure 108b, such that a current I passes through the first conductive layer structure 108a, the opening structure P and the second conductive layer structure 108b. In FIG. 1, the dash line for representing the path of the current I is merely a schematic path, and the path of the current I is not limited thereto. Based on Ohm's law, a resistance is related to the voltage difference and the current I. The resistance is related to the quality of the conductor post 106 disposed in the opening structure P. Therefore, a defect, such as current leakage or open circuit of the conductor post 106 in the opening structure P, can be detected and determined based on the resistance.

FIG. 2 illustrates a top view diagram showing a semiconductor structure 10 in FIG. 1. In FIG. 2, parts of the elements are simplified for convenience of description. Besides, parts of the elements are not illustrated according to and actual proportion, to highlight the characteristics of the embodiments of the invention. As shown in FIG. 2, the first conductive layer structure 108a and the second conductive layer structure 108b further couples to a first pad 110a and a second pad 110b, respectively. The first pad 110a and the second pad 110b are for example but not limited to aluminum pads. In step of testing the quality of the conductor post 106 in the opening structure P, the first pad 110a and the second pad 110b are disposed for providing a contact space for probes.

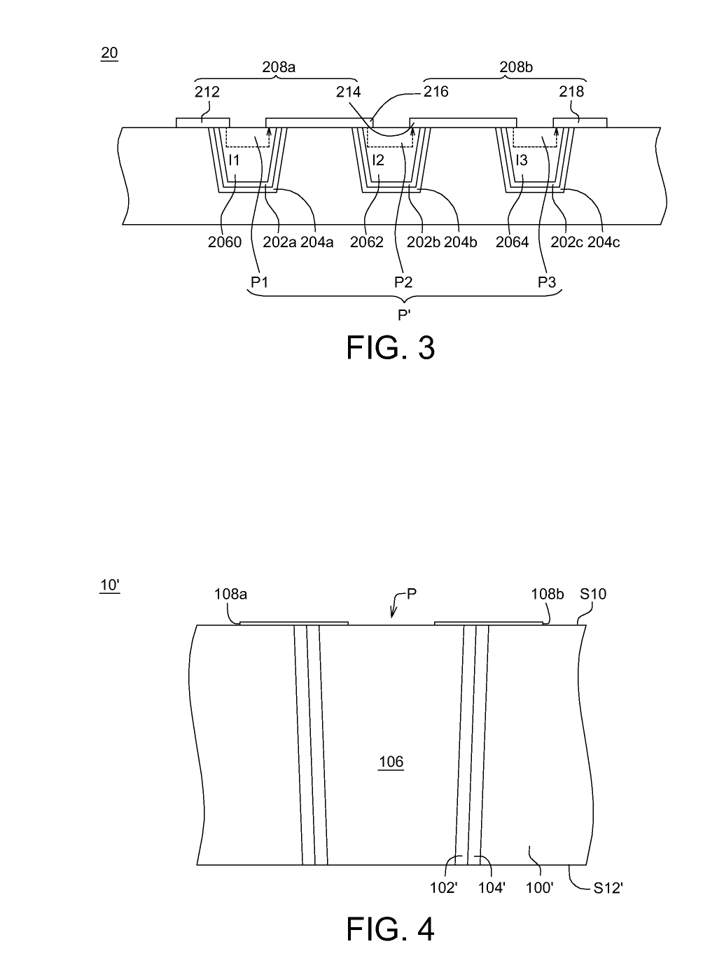

Referring to FIG. 3, which illustrates a diagram showing a cross section view of semiconductor structure according to one embodiment of the invention. As shown in FIG. 3, opening structure P′ comprises a plurality of opening P1, opening P2 and opening P3, each opening P1, opening P2 and opening P3 can be similar to the opening structure P in FIG. 1, a barrier layer 202a, a barrier layer 202b, a barrier layer 202c, an oxide layer 204a, an oxide layer 204b and an oxide layer 204c are respectively disposed on the side surfaces and the bottom surfaces of the opening P1, opening P2 and opening P3. The similarities between the structures in FIG. 1 and FIG. 3 are not repeated herein. Besides, merely three openings (opening P1˜P3) are illustrated herein, and the invention is not limited thereto, the semiconductor structure can comprise more openings. The conductor post 2060, the conductor post 2062 and the conductor post 2064 are respectively disposed in each opening P1, opening P2 and opening P3.

The first conductive layer structure 208a comprises a first conductive layer 212 and a second conductive layer 214, the second conductive layer structure 208b comprises a third conductive layer 216 and a forth conductive layer 218. As shown in FIG. 3, the first conductive layer 212, the second conductive layer 214, the third conductive layer 216 and the forth conductive layer 218 are interlacedly arranged, and respectively electrically connected to the conductor post 2060, the conductor post 2062 and the conductor post 2064. The first conductive layer 212 and the third conductive layer 216 are disposed at two opposite sides with respect to a central axis of the opening P1. The second conductive layer 214 and the third conductive layer 216 are disposed at opposite sides of a central axis of the opening P2. The second conductive layer 214 and the forth conductive layer 218 are disposed at opposite sides of a central axis of the opening P3.

In FIG. 3, the semiconductor structure 20 can be used to detect an opening structure P′ comprising a plurality of opening (P1˜P3), the detecting method for opening structure P′ is similar to that of the opening structure P in FIGS. 1˜2. A voltage difference between two opposite sides of the opening structure P′ can be applied, and the first conductive layer structure 208a and the second conductive layer structure 208b can be respectively coupled to pads (not illustrated) for probe contacting. The voltage difference is between the first conductive layer structure 208a and an adjacent second conductive layer structure 208b. That is, a voltage difference is between the first conductive layer 212 and an adjacent third conductive layer 216, and a voltage difference is between the second conductive layer 214 and an adjacent forth conductive layer 218.

In this case, a current I1 is passing through the first conductive layer 212, the opening P1 and the third conductive layer 216, a current I2 is passing through the third conductive layer 216, the opening P2 and the second conductive layer 214, and a current I3 is passing through the second conductive layer 214, the opening P3 and the forth conductive layer 218. A resistance can be obtained by the voltage difference and the current, and whether there is a defect exists in the conductor post 2060, the conductor post 2062 and the conductor post 2064 can be determined.

In above embodiments, the first conductive layer structure 108a, the second conductive layer structure 108b, the first conductive layer structure 208a and the second conductive layer structure 208b are for example but not limited to a first metal layer (M1) procedure in a manufacturing process. In one embodiment, a voltage difference can be provided between the first conductive layer structure 108a and the second conductive layer structure 108b (the first conductive layer structure 208a and the second conductive layer structure 208b) after the first metal layer procedure, for determining a quality of the conductor post 106 (or the conductor post 2060, the conductor post 2062 and the conductor post 2064).

During the detection process, merely parameter and interfaces between the opening structure P, the first conductive layer structure 108a, the second conductive layer structure 108b, the first pad 110a and the second pad 110b (or the openings P1˜P3, the first conductive layer structure 208a, the second conductive layer structure 208b and pads respectively coupling to the first conductive layer structure 208a and the second conductive layer structure 208b) the conductor post 106 (or the conductor post 2060, the conductor post 2062 and the conductor post 2064) are needed to be considered, the detecting process and complexity of result analysis can be simplified, thereby the detecting process for the opening structure P (or opening structure P′) can be performed in a fast speed and simplified process. In other embodiments, the process can be adjusted based on the manufacturing requirement. The testing method for the opening structure P (or opening structure P′) can be performed after a second metal layer process (M2) or a further process.

FIG. 4 illustrates a diagram showing a substrate of the semiconductor structure in FIG. 1 after an unilateral thinning process. Referring to FIGS. 1 and 4, when the quality of the conductor post 106 in the opening structure P is tested, a thinning process (such as CMP process) can be performed to polishing the second surface S12 of the substrate 100, until the barrier layer 102 and the oxide layer 104 on the bottom surface S2 of the opening structure P are totally removed.

After the thinning process, a semiconductor structure 10′ can be obtained, the semiconductor structure 10′ comprises a polished substrate 100′, a polished barrier layer 102′ and a polished oxide layer 104′. The opening structure P is exposed from the first surface S10 and the polished second surface S12′.

In one embodiment, the substrate 100 can be a silicon substrate, and the opening structure P can be a through-silicon via (TSV). In one embodiment, an active element (not illustrated) is further disposed to a peripheral area of the opening structure P in the substrate 100, the active element can be NMOS and PMOS. In a via-middle process, an active element is formed before the TSV process. In another one embodiment, the opening structure P in the substrate 100 without an active element can be used as an interposer to connect two chips in 3D IC technology.

After the quality test of the conductor post 106 in the opening structure P, further process can be performed after the first conductive layer structure 108a and the second conductive layer structure 108b. For example, if the first conductive layer structure 108a and the second conductive layer structure 108b are the n^{th} metal layer, the process for forming via, the (n+1)^{th}, (n+2)^{th}, (n+3)^{th} metal layers . . . can be performed according to the requirement of the manufacturing process.

### Second Embodiment

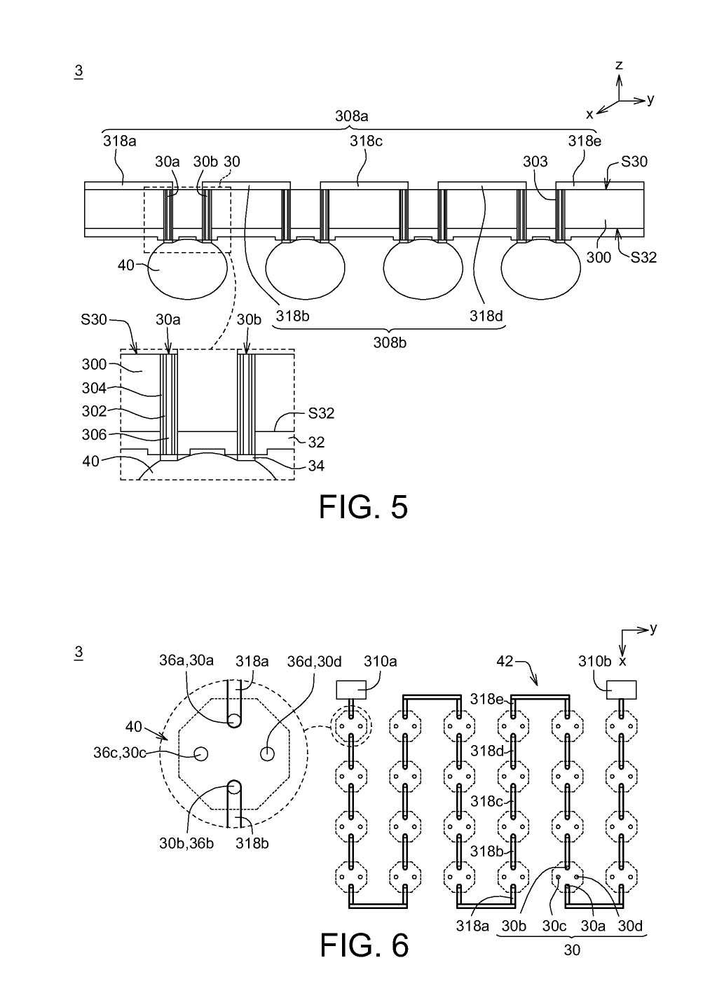

FIG. 5 illustrates a diagram showing a part of a cross section view of a semiconductor structure according to one embodiment of the invention. In FIG. 5, the semiconductor structure 3 is shown in a cross section view from y-z plane view, the semiconductor structure 3 comprises a substrate 300, a barrier layer 302, an oxide layer 304, a conductor post 306, a first conductive layer structure 308a, a second conductive layer structure 308b, an insulating layer 32, a conductive pad 34 and a conductive bump 40.

The substrate 300 has an opening structure, the opening structure can comprise a plurality of TSV sets 30, oxide layer 304 and barrier layer 302 are respectively disposed on a side surface and a bottom surface of the TSV sets 30. The conductor post 306 is disposed in the TSV sets 30, and covers the barrier layer 302 and the oxide layer 304. The first conductive layer structure 308a and the second conductive layer structure 308b are respectively disposed at two opposite sides of a central axis the TSV sets 30, to electrically connected to the conductor post 306. In order to highlight the characteristics of the embodiments of the invention, parts of the elements are not illustrated according to and actual proportion.

As shown in FIG. 5, each TSV set 30 comprises two opening 30a and opening 30b. A terminal of the opening 30a is connected to the first conductive layer structure 308a, and a terminal of the opening 30b is connected to the second conductive layer structure 308b. Another terminal of the opening 30a and another terminal of the opening 30b are electrically connected to a first connecting point 36a and a second connecting point 36b (illustrated in FIG. 6) of the conductive bump 40 respectively. The opening 30a and the opening 30b are electrically connected with each other by the conductive bump 40.

In one embodiment, the substrate 300 has a first surface S30 and a second surface S32 opposite to the first surface S30. The opening 30a and the opening 30b of the TSV set 30 penetrate through and exposed from first surface S30 and second surface S32. The first conductive layer structure 308a and penetrate second conductive layer structure 308b are disposed on the first surface S30 of the substrate 300. The manufacturing method and material of the conductor post 306 can be the same as that of the conductor post 106 in FIG. 1.

The dimension (such as height) of the TSV set 30 is at least ten times greater than that of the first conductive layer structure 308a and the second conductive layer structure 308b. In one embodiment, the dimension (such as height) of the TSV set 30 is 100 times greater than that of the first conductive layer structure 308a and the second conductive layer structure 308b, and the invention is not limited thereto.

A voltage difference (not illustrated) is between the first conductive layer structure 308a and second conductive layer structure 308b, such that a current passes through the first conductive layer structure 308a, the TSV set 30 and the second conductive layer structure 308b. A resistance can be obtained from the voltage difference and the current, the resistance is related to a quality of an electrical connection between the TSV set 30 and conductive bump 40. Therefore, a defect (such as an open circuit or current leakage) between the TSV set 30 and the conductive bump 40 can be detected based on the resistance.

Referring to an enlarge view in FIG. 5, in one embodiment, a bottom surface of the substrate 300 can be etched by a reactive ion etching (RIE) process, such that conductor post 303 protrudes from a second surface S32 of the substrate 300. Then, an insulating layer 32 can be formed on the second surface S32 of the substrate 300 and the protrude conductor post 303 by a chemical vapor deposition (CVD) process. Then, a chemical mechanical polishing (CMP) process can be used to polish the insulating layer 32, until the conductor post 303 is exposed from the insulating layer 32. Then, a conductive pad 34 can be formed on the exposed conductor post 303. Then, a conductive bump 40 can be formed on the conductive pad 34 for electrically connecting to the conductor post 303. The above process can be adjusted according to the requirement of the manufacturing process, and the invention is not limited thereto.

FIG. 6 illustrates a testing method with a diagram showing a top view of a semiconductor structure in FIG. 5 in one direction of x-y plane. As shown in FIG. 6, the semiconductor structure 3 comprises a plurality of TSV sets 30, each TSV set 30 comprises a plurality of opening 30a, opening 30b, opening 30c and opening 30d arranged into an opening matrix. The first conductive layer structure 308a (illustrated in FIG. 5) comprises a plurality of first conductive layers 318a, first conductive layer 318c and first conductive layer 318e. The second conductive layer structure 308b (illustrated in FIG. 5) comprises a plurality of second conductive layer 318b and second conductive layer 318d. The first conductive layer 318a, the first conductive layer 318c and the first conductive layer 318e and the second conductive layer 318b and the second conductive layer 318d are interlacedly arranged.

Referring to FIG. 6, the semiconductor structure 3 further comprises a conductive bump matrix 42, which comprises a plurality of conductive bumps 40 disposed at one side of the opening matrix (along the z axis, toward the paper), and first conductive layer structure 308a and the second conductive layer structure 308b are electrical connected to another side of the opening matrix 42 (along the z axis, out of the paper), such that each conductive bump 40 is electrically connected to one side of at least two adjacent opening 30a and opening 30b of the opening matrix 42. The first conductive layer 318a of the first conductive layer structure 308a and the second conductive layer 318b of the second conductive layer structure 308b are respectively connected to the another side of the at least two adjacent opening 30a and opening 30b.

The testing method for the electrical connection between the opening and the conductive bump showing in FIG. 6 is for the openings along a y axis direction, such as the opening 30a and 30b respectively coupling to the first connecting point 36a and the second connecting point 36b of the conductive bump 40. By applying voltage difference between the first pad 310a and the second pad 310b to generate a current passing through, such that voltage differences exist between the first conductive layer 318a, the first conductive layer 318c, the first conductive layer 318e, and adjacent second conductive layer 318b and second conductive layer 318d. A resistance can be obtained according to the voltage difference and the current, and an electrical connection quality between the TSV sets 30 and the conductive bump can be determined.

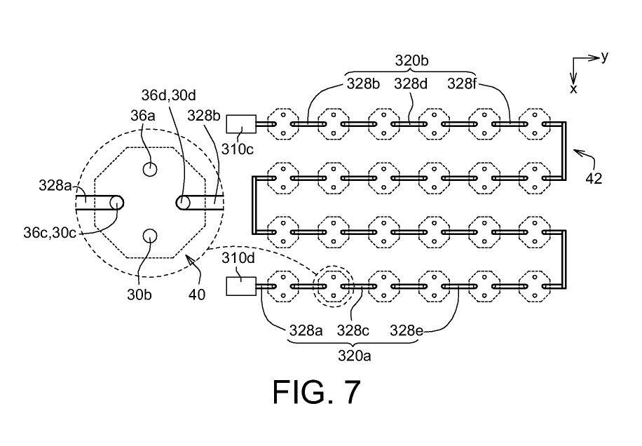

FIG. 7 illustrates a testing method with a diagram showing a top view of a semiconductor structure in FIG. 5 in another one direction of x-y plane. In FIG. 7, the semiconductor structure 3 is similar to that in FIG. 6, the same element is represented by the same reference number, and the similarities are not repeated herein. The differences between FIGS. 6 and 7 is that the testing method for semiconductor structure 3 in FIG. 7 is for openings arranged along x axis, such as the opening 30c and opening 30d respectively couple to the third connecting point 36c and the fourth connecting point 36d of the conductive bump 40.

The first conductive layer structure 320a comprises a plurality of first conductive layer 328a, first conductive layer 328c and first conductive layer 328e. The second conductive layer structure 320b comprises a plurality of second conductive layer 328b, second conductive layer 328d and second conductive layer 328f. The first conductive layer 328a, the first conductive layer 328c and the first conductive layer 328e and the second conductive layer 328b, the second conductive layer 328d and the second conductive layer 328f are interlacedly arranged.

By applying a voltage difference between the first pad 310c and the second pad 310d to generate a current passing through, such that voltage differences between each first conductive layer 328a, first conductive layer 328c and first conductive layer 328e and adjacent second conductive layer 328b, second conductive layer 328d and second conductive layer 328f. An electrical connection quality between the TSV sets 30 and a conductive bump 40 can be determined according to a resistance that is related to the voltage difference and the current.

In one embodiment, the method in first embodiment (FIGS. 1˜3) can be used to confirm the quality of the conductor post in the opening structure. Then, the substrate can be polished such that the opening structure is exposed from a bottom surface of the substrate. Then, an electrical connection between the conductive bump 40 and the opening structure can be determined by applying voltage difference between two adjacent openings of the openings (that is, between the first conductive layer and the second conductive layer), such that a current passing the two adjacent openings. The quality of electrical connection between the opening and the conductive bump can be determined according to resistance obtained from the current and the voltage difference.

Based on the above, the testing method according to the embodiments of the invention can determine the quality (such as a reliability and a stability) of the opening structure. In one embodiment, the quality of the conductor post in the opening structure can be determined to check whether there is a defect of an open circuit or current leakage after the first metal layer procedure. In one embodiment, the quality of the electrical connection between the opening structure and the conductive bump can be determined. In one embodiment, the detecting process can be simplified and the complexity can be reduced, so that the testing process of the opening structure can speed up and simplified.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a substrate, having an opening structure;
a dielectric layer, disposed on a side surface of the opening structure;
a conductor post, disposed in the opening structure and covering the dielectric layer; and
a first conductive layer structure and a second conductive layer structure, electrically connected to the conductor post, wherein the first conductive layer structure and the second conductive layer structure are respectively disposed at opposite sides of a central axis of the opening structure, a voltage difference exists between the first conductive layer structure and the second conductive layer structure, such that a current passes through the first conductive layer structure, the opening structure and the second conductive layer structure, a resistance is related to the voltage difference and the current, wherein a dimension of the opening structure is at least 10 times greater than a dimension of the first conductive layer structure and a dimension of the second conductive layer structure.

2. The semiconductor structure according to claim 1, wherein the substrate is a silicon substrate, and the opening structure comprises a through-silicon via (TSV).

3. The semiconductor structure according to claim 1, further comprises:
an active element, disposed at a peripheral area of the opening structure.

4. The semiconductor structure according to claim 1, wherein the opening structure comprises a plurality of opening, the conductor post is disposed in each of the openings, the first conductive layer structure comprises a plurality of first conductive layers, the second conductive layer structures comprises a plurality of second conductive layer, the first conductive layers and the second conductive layers are interlacedly arranged and electrical connecting to the conductor post, each of the first conductive layers and each of the second conductive layers are respectively disposed at opposite sides of a central axis of each of the openings, and the voltage difference exist between each of the first conductive layers and an adjacent second conductive layer of the second conductive layers.

5. The semiconductor structure according to claim 1, wherein the resistance is related to a quality of the conductive layer disposed in the opening structure.

6. The semiconductor structure according to claim 1, wherein the dielectric layer comprises an oxide layer, and the semiconductor structure further comprises a barrier layer disposed on the dielectric layer, and the dimension of the opening structure is at least 100 times greater than the dimension of the first conductive layer structure and the second conductive layer structure.

7. The semiconductor structure according to claim 6, wherein the substrate has a first surface and a second surface opposite to the first surface, the first conductive layer structure and the second conductive layer structure are disposed on the first surface of the substrate, extend from the first surface of the substrate to the conductor post, exceed the dielectric layer and the barrier layer and contact a surface of the conductor post.

8. The semiconductor structure according to claim 6, wherein the opening structure merely passes through one side of the substrate, and the dielectric layer is further disposed on a bottom surface of the opening structure.

9. The semiconductor structure according to claim 1, further comprising a conductive bump, and the opening structure comprising a plurality of TSV sets, each of the TSV sets comprising:
a first opening, a terminal of the first opening is connected to the first conductive layer structure; and
a second opening, a terminal of the second opening is connected to the second conductive layer structure, another terminal of the first opening and another terminal of the second opening respectively electrical connecting to a first connecting point and a second connecting point of the conductive bump, wherein the first opening and the second opening are electrically connecting with the conductive bump, and the resistance is related to a quality of an electrical connection between the first opening, the second opening and the conductive bump.

10. The semiconductor structure according to claim 1, wherein the opening structure corresponds a plurality of TSV sets and comprises a plurality of opening arranged into an opening matrix, the first conductive layer structure comprises a plurality of first conductive layers, and the second conductive layer structure comprises a plurality of second conductive layers, the first conductive layers and the second conductive layers are interlacedly arranged, and the semiconductor structure further comprises:
a conductive bump matrix, comprises a plurality of conductive bumps disposed at one side of the opening matrix, and the first conductive layers and the second conductive layers are electrically connected to another one side of the opening matrix, such that each of the conductive bumps is electrically connected to one side of at least two adjacent openings in the opening matrix, one of the first conductive layers and one of the second conductive layers are respectively connected to another one side of the at least two adjacent openings, wherein the resistance is related to an electrical connection between the opening matrix and the conductive bump matrix.

11. The semiconductor structure according to claim 1, wherein the substrate has a first surface and a second surface opposite to the first surface, the semiconductor structure further comprises an insulating layer disposed on the second surface and at a peripheral area of the opening structure.

12. A method for testing a semiconductor structure, comprising:
providing a semiconductor structure, the semiconductor structure comprising a substrate, a dielectric layer, a conductor post, a first conductive layer structure and a second conductive layer structure, the substrate having an opening structure, the dielectric layer disposed on a side surface of the opening structure, the conductor post disposed in the opening structure and covering the dielectric layer, wherein the first conductive layer structure and the second conductive layer structure are electrically connected with the conductor post, and the first conductive layer structure and the second conductive layer structure are respectively disposed at opposite sides of a central axis of the opening structure, and a dimension of the opening structure is at least 10 times greater than a dimension of the first conductive layer structure and a dimension of the second conductive layer structure;
applying a voltage difference between the first conductive layer structure and the second conductive layer structure;
measuring a current passing through the first conductive layer structure, the opening structure and the second conductive layer structure;
obtaining a resistance according to the voltage difference and the current; and
determining a testing result according to the resistance.

13. The method for testing a semiconductor structure according to claim 12, wherein the opening structure comprise a plurality of openings, the conductor post is in each of the openings, the first conductive layer structure comprises a plurality of first conductive layers, the second conductive layer structure comprises a plurality of second conductive layers, the first conductive layers and the second conductive layers are interlacedly arranged and electrically connecting to the conductor post, each of the first conductive layers and each of the second conductive layers are respectively disposed at opposite sides of a central axis of each of the openings, and the step of applying the voltage difference between the first conductive layer structure and the second conductive layer structure comprises:
applying the voltage difference between each of the first conductive layers and an adjacent second conductive layer of the second conductive layers.

14. The method for testing a semiconductor structure according to claim 12, wherein the step of determining the testing result according to the resistance comprises:
determining a quality of the conductive layer in the opening structure according to the resistance.

15. The method for testing a semiconductor structure according to claim 12, wherein in step of providing the semiconductor structure, the dielectric layer comprises an oxide layer, and further provides a barrier layer disposed on the oxide layer, wherein the dimension of the opening structure is at least 100 times greater than the dimension of the first conductive layer structure and the dimension of the second conductive layer structure.

16. The method for testing a semiconductor structure according to claim 15, wherein in step of providing the semiconductor structure, the opening structure merely passes through one side of the substrate, the dielectric layer is further disposed on a bottom surface of the opening structure, and the semiconductor structure further comprises an active element disposed at a peripheral side of the opening structure.

17. The method for testing a semiconductor structure according to claim 15, wherein the substrate has a first surface and a second surface opposite to the first surface, in step of providing the semiconductor structure further comprises:
disposing the first conductive layer structure and the second conductive layer structure on the first surface of the substrate, and extends from the first surface of the substrate toward the conductor post, exceed the dielectric layer and the barrier layer and contact a surface of the conductor post.

18. The method for testing a semiconductor structure according to claim 12, wherein the opening structure passes through two sides of the substrate, the opening structure comprises a first opening and a second opening, one side of the first opening is connected to the first conductive layer structure, one side of the second opening is connected to the second conductive layer structure, in step of providing the semiconductor structure, further comprises:
providing a conductive bump disposed at another side of the first opening and another side of the second opening; and
electrically connecting a first connecting point of the conductive bump to the another side of the first opening, and electrically connecting a second connecting point of the conductive bump and the another side of the second opening, wherein in step of determining the testing result according to the resistance comprises:
determining an electrical connection between the first opening, the second opening and the conductive bump according to the resistance.

19. The method for testing a semiconductor structure according to claim 12, wherein the opening structure comprises a plurality of opening, the openings are arranged into an opening matrix, the first conductive layer structure comprises a plurality of first conductive layers, and the second conductive layer structure comprises a plurality of second conductive layers, the first conductive layers and the second conductive layers are interlacedly arranged, in step of providing the semiconductor structure, further comprises:
providing a conductive bump matrix, comprising a plurality of conductive bumps disposed at one side of the opening matrix, each of the conductive bumps are electrically connected to one side of at least two adjacent openings in the opening matrix; and
electrically connecting the first conductive layers and the second conductive layers to another one side of the opening matrix, such that one of the first conductive layers and one of the second conductive layers are respectively connected to another one side of the at least two adjacent openings, and step of determining the testing result according to the resistance comprises:
determining an electrical connection between the opening matrix and the conductive bump matrix according to the resistance.

20. The method for testing a semiconductor structure according to claim 12, wherein the opening structure comprises a plurality of openings, the openings merely passes through one side of the substrate, the dielectric layer comprises an oxide layer disposed on the side surface and a bottom surface of the opening structure, and further provides a barrier layer disposed on the oxide layer and corresponding to the side surface and the bottom surface of the opening structure, and step of determining the testing result according to the resistance comprises:
determining a quality of the conductive layer in the opening structure according to the resistance; and
performing a polishing process to the substrate, such that the opening structure is exposed from the one side of the substrate;
providing a conductive bump disposed adjacently to the one side of the substrate and electrically connecting to the opening structure;
applying another voltage difference to two adjacent openings of the openings, such that another current passing through the two adjacent openings, wherein another resistance related to the another voltage difference and the another current is obtained, and a quality of an electrical connection between the conductive bump and the two adjacent openings is determined according to the another resistance.
